(19) United States
(12) Patent Application Publication
(10) Pub. No.: US 2024/0420930 A1
(43) Pub. Date: Dec. 19, 2024

(54) SUBSTRATE PROCESSING APPARATUS

(71) Applicant: SAMSUNG ELECTRONICS CO., LTD., Suwon-si (KR)

(72) Inventors: Changho Kim, Suwon-si (KR); Ho-Jun Lee, Suwon-si (KR); Kyung-Sun Kim, Suwon-si (KR); Sang-Woo Kim, Suwon-si (KR); Donghyeon Na, Suwon-si (KR); Seungbo Shim, Suwon-si (KR); Sung-Hyeon Jung, Suwon-si (KR)

(73) Assignee: Pusan National University Industry-University Cooperation Foundation, Busan (KR)

(21) Appl. No.: 18/414,681

(22) Filed: Jan. 17, 2024

(30) Foreign Application Priority Data
Jun. 19, 2023 (KR) 10-2023-0078174

(51) Int. Cl. H01J 37/32

(52) U.S. Cl. CPC H01J 37/32669; H01J 37/32715

(57) ABSTRACT

A substrate processing apparatus according to an embodiment includes: a chamber providing a processing space; a support member disposed in the processing space and configured to support a substrate during a process treatment; an antenna providing energy for plasma excitation into the processing space; and an inner electromagnet disposed outside the processing space.

### CROSS-REFERENCE TO RELATED APPLICATION

This application claims priority to and the benefit of Korean Patent Application No. 10-2023-0078174 filed in the Korean Intellectual Property Office on Jun. 19, 2023, the entire contents of which are incorporated by reference herein.

### TECHNICAL FIELD

The present disclosure relates generally to a substrate processing apparatus, e.g., for producing a semiconductor or other electronic device.

### DISCUSSION OF RELATED ART

To manufacture a semiconductor device, various processes such as photolithography, etching, ashing, ion implantation, thin film deposition, and cleaning are performed on a substrate to form a desired pattern on the substrate. Among these processes, the etching process is a process that removes a selected heating area of a film formed on the substrate. The process may include wet etching and/or dry etching.

Among these processes, a plasma etching device is used for the dry etching. In general, to form a plasma, an electromagnetic field is created in an inner space of a chamber, and the electromagnetic field excites a process gas provided within the chamber to a plasma state.

The plasma is an ionized gas state composed of ions, electrons, radicals, and the like. The plasma is created by very high temperatures, strong electric fields, and/or radio frequency (RF) electromagnetic fields. The manufacturing process for etching a semiconductor device may be performed by ionic particles contained in the plasma colliding with the substrate. During the processing treatments, the substrate is heated by the plasma.

### SUMMARY

Embodiments of the present disclosure provide a substrate processing apparatus capable of effectively processing a substrate by controlling a plasma state.

A substrate processing apparatus, according to an embodiment, may include: a chamber providing a processing space; a support member disposed in the processing space and configured to support a substrate during a process treatment thereof; an antenna providing energy for plasma excitation into the processing space; and an inner electromagnet disposed outside the processing space.

A substrate processing apparatus, according to an embodiment, may include: a chamber providing a processing space; a cover member disposed on an upper portion of the chamber and configured to shield the processing space; a support member disposed in the processing space and configured to support a substrate during a process treatment; an antenna providing energy for plasma excitation into the processing space; an inner electromagnet disposed outside the processing space and having an annular surface facing the processing space with the cover member therebetween; and an outer electromagnet disposed outside the processing space and outside a perimeter of the inner electromagnet.

A substrate processing apparatus, according to an embodiment, may include: a chamber providing a processing space; a cover member disposed on an upper portion of the chamber and configured to shield the processing space; a support member disposed in the processing space and configured to support a substrate during a process treatment; an antenna providing energy for plasma excitation into the processing space; an inner electromagnet disposed outside the processing space and disposed facing the processing space with the cover member therebetween; and an outer electromagnet disposed outside the processing space and outside a perimeter of the inner electromagnet, in which the cover member may include: a cover frame provided in a plate structure and having coupling slots between portions of the plate structure, each of the coupling slots including a dielectric window.

### BRIEF DESCRIPTION OF THE DRAWINGS

FIG. 1 is a cross-sectional view illustrating a substrate processing apparatus, according to an embodiment.

FIG. 2 is a view illustrating a cover member of FIG. 1.

FIG. 3 is a top plan view of an inner electromagnet and an outer electromagnet.

FIG. 4 is a view illustrating a control relationship of the substrate processing apparatus.

FIG. 5 is a view illustrating a direction of magnetic line of force formed between the inner electromagnet and the outer electromagnet.

FIG. 6 is a view illustrating a direction of magnetic line of force formed between the inner electromagnet and the outer electromagnet, according to another example.

FIG. 7 is a view illustrating a control relationship of a substrate processing apparatus, according to another embodiment.

FIGS. 8 and 9 are views illustrating a vertical position relationship of the inner electromagnet and the outer electromagnet.

FIG. 10 is a view illustrating an inner electromagnet and an outer electromagnet, according to another embodiment.

FIG. 11 is a view illustrating control relationship of a substrate processing apparatus including the inner electromagnet and outer electromagnet of FIG. 10.

FIGS. 12, 13, 14 and 15 are views illustrating a case where a magnetic line of force is formed to be directed from a lower portion of the inner electromagnet to a lower portion of the outer electromagnet.

FIGS. 16, 17, 18 and 19 are views illustrating a case where a magnetic line of force is formed to be directed from the lower portion of the outer electromagnet to the lower portion of the inner electromagnet.

FIGS. 20 and 21 are views illustrating a vertical position relationship of a plurality of inner electromagnets and a plurality of outer electromagnets.

FIG. 22 is a view illustrating a vertical position relationship of a plurality of inner electromagnets.

FIG. 23 is a view illustrating a vertical position relationship of a plurality of outer electromagnets.

### DETAILED DESCRIPTION OF EMBODIMENTS

Hereinafter, several embodiments of the present disclosure will be described in detail with reference to the accompanying drawings so that those of ordinary skill in the art to which the present disclosure pertains may easily carry out the embodiments. The present disclosure may be implemented in various different ways and is not limited to the embodiments described herein.

For brevity, embodiments described hereafter may include other components for which description herein is omitted. Herein, the same or similar constituent elements may be designated by the same reference numerals throughout the specification and drawings.

In addition, a size and a thickness of each constituent element illustrated in the drawings are arbitrarily shown for convenience of description, but the present disclosure is not limited thereto. To clearly describe several layers and regions, thicknesses thereof may be enlarged in the drawings. In the drawings, the thicknesses of some layers and regions may be exaggerated for convenience of description.

In addition, when a first component such as a layer, a film, a region, or a plate is described as being disposed “above” or “on” a second component, the first component may be disposed directly on the second component in some embodiments, and “indirectly on” the second component in other embodiments (in the latter case, one or more intervening components are situated between the first and second components). In addition, when a component is described as being disposed “above” or “on” a reference part, the component may be disposed “above” or “below” the reference part, but this configuration does not necessarily mean that the component is disposed “above” or “on” the reference part in a direction opposite to gravity.

Throughout the specification, the phrase “in a plan view” means when an object is viewed from above, and the phrase “in a cross-sectional view” means when a cross section made by vertically cutting an object is viewed from a lateral side.

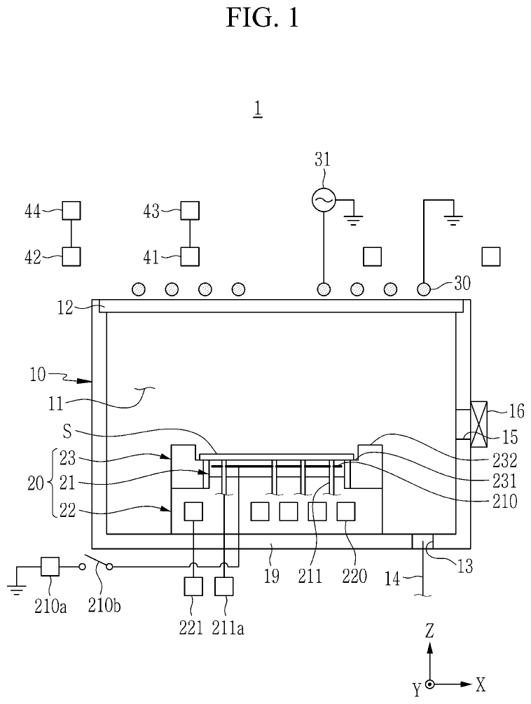

FIG. 1 is a cross-sectional view illustrating a substrate processing apparatus, 1, according to an embodiment. The substrate processing apparatus 1 includes a chamber 10, a support member 20, an antenna 30, an inner electromagnet 41, and an outer electromagnet 42.

The substrate processing apparatus 1 processes a substrate S using plasma. In an example, the substrate processing apparatus 1 may perform an etching process, a deposition process, an ashing process, or the like on the substrate S using the excited plasma. The substrate S may be a wafer for manufacturing a semiconductor device.

The chamber 10 provides a processing space 11 therein in which a process of treating the substrate S is performed. The chamber 10 may include or be composed of a metallic material, such as aluminum. The chamber 10 may be grounded. The chamber 10 has an exhaust hole 13 formed on one side thereof, e.g., within a base 19 of the chamber 10. The exhaust hole 13 is connected to an exhaust line 14. Reaction by-products generated during the process and gases that remain in an inner space of the chamber 10 may be discharged to the outside through the exhaust hole 13. Through the exhaust process, the interior of the chamber 10 may be depressurized to a predetermined pressure.

Herein, to facilitate understanding, structural features and the relative arrangement of components of the substrate processing apparatus 1 are described in the context of an xyz cartesian coordinate system, as illustrated in FIG. 1. To this end, the z direction may be referred to interchangeably as the vertical direction and is direction normal to a major surface of the base 19 (e.g., the lower surface). Heights described for components/features are heights in the z direction relative to the base 19. A horizontal direction may be referred to as any direction in the xy plane, which is parallel to the base 19. It is noted, however, that the substrate processing apparatus 1 need not operate in the orientation shown in FIG. 1. For instance, the “vertical direction’ is not necessarily a direction of gravity and the “horizontal direction” is not necessarily a direction parallel to the ground.

The chamber 10 has an opening 15 formed on one side thereof. The opening 15 is provided as a path through which the substrate S is inserted or removed. The opening 15 may be opened and closed by a door 16.

The support member 20 is disposed inside the chamber 10, e.g., in a lower portion of the processing space 11. The support member 20 supports the substrate S and may adsorb the substrate S using an electrostatic force.

The support member 20 may include a dielectric plate 21, a body 22, and a focus ring 23.

The dielectric plate 21 is disposed on an upper portion of the support member 20. The dielectric plate 21 may be provided as a plate structure having a uniform thickness. An outer perimeter of the dielectric plate 21 may be of a circular shape. The dielectric plate 21 may be composed entirely or primarily of dielectric material. The substrate S is placed on an upper surface of the dielectric plate 21. An area of the upper surface of the dielectric plate 21 may be smaller than an area of the substrate S. The upper surface of the dielectric plate 21 may have a smaller radius than the substrate S. Accordingly, when the substrate S is disposed on the upper surface of the dielectric plate 21, a peripheral area of the substrate S is disposed outside the perimeter of the dielectric plate 21.

The substrate S may be in the shape of a plate, e.g., a disc, with a thickness dimension between an upper surface and a lower surface. The upper and lower surfaces of the substrate S may each be referred to interchangeably as a major surface or a face. Likewise, the upper surface of the plate 21 may be called a face or a major surface thereof, and may be a planar surface lying in the horizontal plane. When the substrate S is supported by the support member 21, the faces of the substrate S may also lie in the horizontal plane and a normal to each of the faces may be vertical. A normal to a face of the substrate S as supported during processing may be parallel to or aligned with a vertical axis running through a center point of each of the inner and outer electromagnets 41 and 42.

An internal electrode 210 may be disposed inside the dielectric plate 21. The internal electrode 210 may be provided in a shape approximately corresponding to the upper surface of the dielectric plate 21. The inner electrode 210 is electrically connected to an adsorption power source 210a. The adsorption power source 210a includes a direct current (DC) power source. A switch 210b may be disposed between the internal electrode 210 and the adsorption power source 210a. When the switch 210b is turned on, the adsorption power source 210a may apply a voltage to the internal electrode 210. An electrostatic force is generated between the internal electrode 210 and the substrate S by the voltage applied by the adsorption power source 210a, and the electrostatic force causes the substrate S to be adsorbed on the dielectric plate 21.

A heat transfer medium supply flow path 211 is formed inside the dielectric plate 21. The heat transfer medium supply flow path 211 extends to the upper surface of the dielectric plate 21, and provides a path through which heat transfer gas is supplied to the upper surface of the dielectric plate 21. The heat transfer medium supply flow path 211 may originate from a heat transfer gas storage portion 211a. The heat transfer gas storage portion 211a supplies the heat transfer gas to the heat transfer medium supply flow path 211. The heat transfer gas may be inert gas. In an example, the heat transfer gas is helium (He). When the heat transfer gas is supplied to the upper surface of the dielectric plate 21 in a state where the substrate S is adsorbed on the upper surface of the dielectric plate 21, the heat transfer gas is present in a space formed between a lower surface of the substrate S and the dielectric plate 21. The heat transfer gas acts as a medium to transfer heat from the substrate S to the support member 20.

The body 22 is disposed at a lower portion of the support member 20. The dielectric plate 21 may be disposed on top of the body 22. In an example, the dielectric plate 21 may be attached to an upper portion of the body 22 by an adhesive layer. The upper portion of the body 22 may be stepped such that the center area thereof is disposed higher than the edge area thereof. The center area of the upper portion of the body 22 may be provided with a shape corresponding to the lower surface of the dielectric plate 21. The dielectric plate 21 may be disposed on top of the center area of the upper portion of the body 22.

A refrigerant flow path 220 may be formed inside the body 22. The refrigerant flow path 220 provides a path through which cooling fluid flows inside the body 22. In an example, the refrigerant flow path 220 may be formed in a helical shape. In addition, the refrigerant flow path 220 may be ring-shaped flow paths having different radii measured from the same center point. In this case, the refrigerant flow path 220 may be configured such that the ring-shaped flow paths are in communication with each other.

Refrigerant flow path 220 is connected to a refrigerant reservoir 221. The refrigerant reservoir 221 supplies refrigerant to the refrigerant flow path 220. Refrigerant circulates through the refrigerant flow path 220 and cools the body 22. As the body 22 is cooled, the dielectric plate 21 and the substrate S are cooled. Thus, heat from the substrate S is transferred to the cooled body 22 through the dielectric plate 21.

At least some areas of the body 22 may include or be composed primarily or entirely of a metallic material. In an example, the entire body 22 is made of metal such as aluminum. Accordingly, the body 22 may function as an electrode.

The focus ring 23 may be disposed in an upper outer area of the support member 20. The focus ring 23 may be disposed on an outer periphery of the dielectric plate 21. The focus ring 23 may be disposed in an upper edge area of the body 22. The focus ring 23 may have a ring shape. An upper portion of the focus ring 23 may be stepped such that an outer portion 232 is higher than an inner portion 231. The upper inner portion 231 of the focus ring 23 may be disposed at a height corresponding to the upper surface of the dielectric plate 21. The upper inner portion 231 of the focus ring 23 is disposed underneath the edge area of the substrate S disposed on an outer side of the dielectric plate 21. The upper outer portion 232 of the focus ring 23 may be disposed to surround the edge area of the substrate S. The focus ring 23 may improve the uniformity of density distribution of the plasma. The focus ring 23 may be worn out in use, by contact with the substrate S or by an electromagnetic force acting on the focus ring 23. As the wear of the focus ring 23 increases, the performance of controlling the density distribution of the plasma decreases. Accordingly, the focus ring 23 may be replaced after a certain period of time or a certain number of times of use.

A cover member 12 may be disposed on an upper portion of the chamber 10 to shield the processing space 11. The cover member 12 allows the energy generated from the antenna 30 to penetrate into the processing space 11. At least some areas of the cover member 12 may be provided with a dielectric.

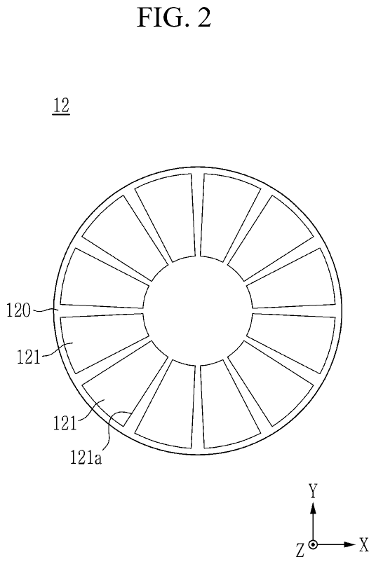

FIG. 2 is a view illustrating a plan view of an example cover member of FIG. 1.

With reference to FIG. 2, the cover member 12 includes a cover frame 120 and a plurality of dielectric windows 121 that form a composite window. (Hereafter, the composite dielectric window may be referred to loosely as a composite dielectric window 121.)

The cover member 12 may have a plate structure with a thickness (in the z direction) smaller than each of its maximum orthogonal dimensions in the xy plane. The cover frame 120 may have a “hub and spoke” plate structure with an outer ring, a central hub region, and a plurality of spoke-shaped structures (“spokes”) connecting the outer ring and the central hub region. The central hub region may be in the form of a circular plate (a disc) and may be composed of dielectric. An outer perimeter of the cover frame 120 may have a shape corresponding to an outer perimeter of the chamber 10. The cover frame 120 may be coupled to the upper portion of the chamber 10. The cover frame 120 may include a metal material such as aluminum. The cover frame 120 may have coupling slots 121a formed therein. The coupling slots 121a may be formed by penetrating the cover frame 120 in the vertical (z) direction. The coupling slots 121a may be arranged along a circumferential path with respect to a center area of the cover frame 120. Each of the coupling slots 121a may have the same shape (e.g., a truncated pie shape as illustrated).

The composite dielectric window 121 may include the plurality of sub-windows 121, each in a shape of a coupling slot 121a that it fills. Each dielectric window 121 is disposed within a respective one of the coupling slots 121a. Each dielectric window 121 may be composed of a dielectric such as quartz.

The antenna 30 provides energy for plasma excitation into the processing space 11. The antenna 30 is disposed outside the processing space 11. The antenna 30 may be disposed adjacent to an upper surface of the cover member 12. The antenna 30 may be disposed on top of the cover member 12.

The antenna 30 may have a ring shape, an arc shape, or the like. The antenna 30 may be a spiral antenna or a helical antenna. The antenna 30 may be electrically connected to an antenna power source (“RF power source”) 31. The antenna power source 31 may be a high frequency power source (e.g., 3-30 MHz) that generates high frequency power. The antenna 30 generates electromagnetic waves through RF power provided by the antenna power source 31. The gas in the processing space 11 may be excited into the plasma by the electromagnetic waves generated by the antenna 30.

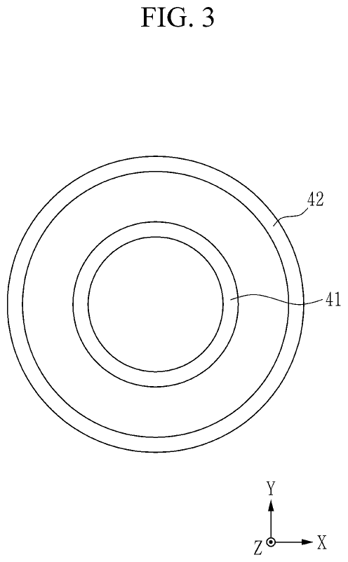

FIG. 3 is a top plan view of an example inner electromagnet 41 and an outer electromagnet 43. The inner electromagnet 41 may be disposed outside the processing space 11. The inner electromagnet 41 may be disposed above the cover member 12 along the horizontal direction (in the xy plane) and facing the processing space 11 with the cover member 12 therebetween. Thus, an annular surface (as shown in FIG. 3) of the inner electromagnet 41 faces the processing space 11. The inner electromagnet 41 may be disposed on a circumference about a vertical (z direction) axis that passes through the center area of the processing space 11. Hence, the inner electromagnetic 41 may be concentric about the vertical axis. In an example, the inner electromagnet 41 may be provided in a shape of a circular ring, an arc shape (e.g., a major arc) with one side cut from a circular ring, or the like. It is noted here that the plan view of FIG. 3 is just a two dimensional profile that omits a structure of terminal ends of each of the inner and outer electromagnets 41 and 42 at which current may be supplied. In this regard, the terminal ends of the inner and outer electromagnets 41 and 42 may have any suitable structure for connection to an electrical power source.

The inner electromagnet 41 may be electrically connected to an inner electromagnet power source 43 (an electricity source). The inner electromagnet power source 43 provides power to operate the inner electromagnet 41.

The outer electromagnet 42 is disposed outside the processing space 11. The outer electromagnet 42 may be disposed on a circumference about a vertical axis that passes through the center area of the processing space 11. The outer electromagnet 42 is disposed beyond the perimeter of the inner electromagnet 41. The outer electromagnet 42 and the inner electromagnet 41 may be arranged concentrically. In an example, the outer electromagnet 42 may be provided in a shape of a circular ring, an arc shape with one side cut from a circular ring, or the like.

An inner perimeter of the outer electromagnet 42 may be larger than the outer perimeter of the chamber 10. Accordingly, in a top plan view, the outer surface of the chamber 10 may be disposed in a space formed inside an inner surface of the outer electromagnet 42.

In some embodiments, the outer electromagnet 42 and the inner electromagnet 41 are disposed at the same height (herein, “height” is measured in the vertical direction). In other embodiments, the outer electromagnet 42 and the inner electromagnet 41 are disposed at different heights.

The outer electromagnet 42 may be electrically connected to an outer electromagnet power source 44. The outer electromagnet power source 44 provides electric power to operate the outer electromagnet 42.

The inner electromagnet 41 and the outer electromagnet 42 form a magnetic field inside the processing space 11. The magnetic field may adjust the behavior of charged particles inside the processing space 11. The magnetic field may increase the residence time of electrons inside the processing space 11 by changing the trajectory of electron movement in the processing space 11. Accordingly, the heating efficiency and ionization reaction by the electrons may be improved, thereby increasing the density of the plasma. In addition, the distribution of the magnetic field may be adjusted so that the density of the plasma in the processing space 11 may be adjusted in accordance with the areas of the magnetic field distribution.

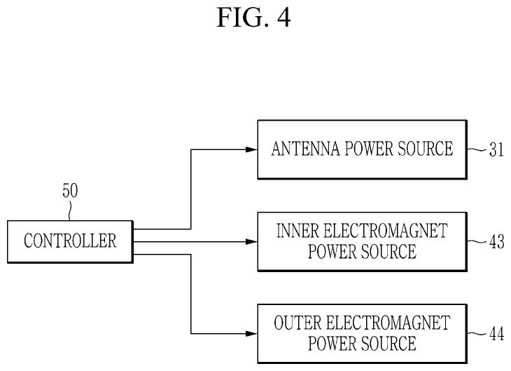

FIG. 4 is a view illustrating an example control relationship of the substrate processing apparatus 10.

With reference to FIG. 4, a controller 50 controls the antenna power source 31, the inner electromagnet power source 43, and the outer electromagnet power source 44.

The controller 50 may control the magnitude of the power (or current) that the antenna power source 31 applies to the antenna 30 by controlling the antenna power source 31.

The controller 50 may control the magnitude of the power (or current) that the inner electromagnet power source 43 applies to the inner electromagnet 41 by controlling the inner electromagnet power source 43.

The controller 50 may control the magnitude of the power (or current) that the outer electromagnet power source 44 applies to the outer electromagnet 42 by controlling the outer electromagnet power source 44.

In an example, the controller 50 is provided as a multi-level pulse controller 50 and may control the magnitude of power (or current) supplied by each of the antenna power source 31, the inner electromagnet power source 43, and the outer electromagnet power source 44. Hereafter, a “control of “power” applied to a component, or “power generated by” the component (e.g., an antenna or electromagnet) may equivalently or alternatively be a “control of current”, or “current generated by” the component, respectively; and vice versa.

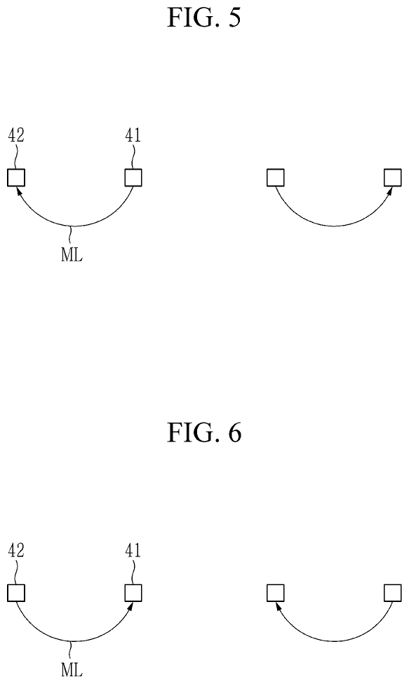

FIG. 5 is a view illustrating a direction of magnetic line of force ML formed between the inner electromagnet 41 and the outer electromagnet 42. The magnetic line of force ML may be a line of maximum force of a magnetic field distribution between the inner and outer electromagnets 41 and 42.

With reference to FIG. 5, the controller 50 may control the inner electromagnet power source 43 and the outer electromagnet power source 44 such that a magnetic line of force ML is formed to be directed from a lower portion of the inner electromagnet 41 toward a lower portion of the outer electromagnet 42. To this end, the controller 50 may control a direction of the current that the inner electromagnet power source 43 supplies to the inner electromagnet 41 such that the lower portion of the inner electromagnet 41 represents the north (N) pole. In addition, the controller 50 may control a direction of the current that the outer electromagnet power source 44 supplies to the outer electromagnet 42 such that the lower portion of the outer electromagnet 42 represents the south (S) pole. Accordingly, a magnetic field may be formed in the processing space 11 in a direction from an inner center area of the processing space 11 toward an outer area thereof.

In this case, the controller 50 may control the magnitude of the current applied to the inner electromagnet 41 and the current applied to the outer electromagnet 42, respectively. The controller 50 may control the magnitude of the current applied to the inner electromagnet 41 to be greater than the magnitude of the current applied to the outer electromagnet 42. In another example, the controller 50 may control the magnitude of the current applied to the inner electromagnet 41 to be smaller than the magnitude of the current applied to the outer electromagnet 42. In still another example, the controller 50 may control the magnitude of the current applied to the inner electromagnet 41 to be the same as the magnitude of the current applied to the outer electromagnet 42. Accordingly, the intensity of the magnetic line of force ML, the shape of the magnetic line of force ML, and the overall magnetic field distribution (the magnetic field pattern) between the inner and outer electromagnets, may be adjusted.

FIG. 6 is a view illustrating a direction of magnetic line of force formed between the inner electromagnet and the outer electromagnet, according to another example.

With reference to FIG. 6, the controller 50 may control the inner electromagnet power source 43 and the outer electromagnet power source 44 such that a maximum magnetic line of force ML is formed to be directed from a lower portion of the outer electromagnet 42 toward a lower portion of the inner electromagnet 41. Here, the controller 50 may control the direction of the current that the outer electromagnet power source 44 supplies to the outer electromagnet 42 such that the lower portion of the outer electromagnet 42 represents the N pole. In addition, the controller 50 may control the direction of the current that the inner electromagnet power source 43 supplies to the inner electromagnet 41 such that the lower portion of the inner electromagnet 41 represents the S pole. Accordingly, a magnetic field may be formed in the processing space 11 in a direction from the outer area of the processing space 11 toward the inner center area thereof.

In this case, the controller 50 may control the magnitude of the current applied to the inner electromagnet 41 and the current applied to the outer electromagnet 42, respectively. The controller 50 may control the magnitude of the current applied to the inner electromagnet 41 to be greater than the magnitude of the current applied to the outer electromagnet 42. In another example, the controller 50 may control the magnitude of the current applied to the inner electromagnet 41 to be smaller than the magnitude of the current applied to the outer electromagnet 42. In yet another example, the controller 50 may control the magnitude of the current applied to the inner electromagnet 41 to be the same as the magnitude of the current applied to the outer electromagnet 42. Accordingly, the intensity of the magnetic line of force ML, the shape of the magnetic line of force ML, and the overall magnetic field distribution (the magnetic field pattern) between the inner and outer electromagnets, may be adjusted.

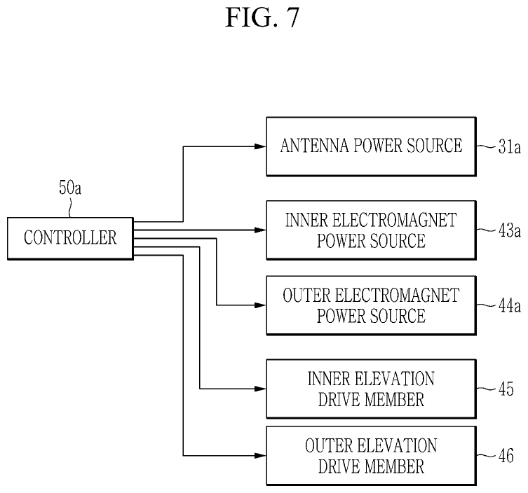

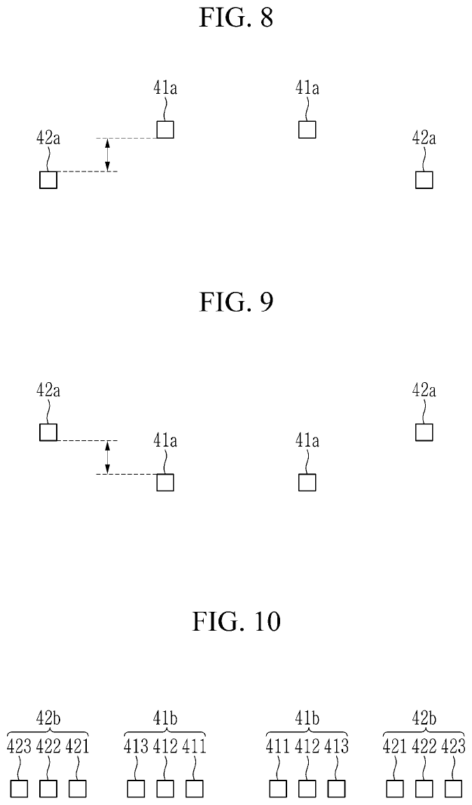

FIG. 7 is a view illustrating a control relationship of a substrate processing apparatus, according to another embodiment, and FIGS. 8 and 9 are views illustrating a vertical position relationship of the inner electromagnet and the outer electromagnet.

With reference to FIGS. 7 to 9, a controller 50a controls an antenna power source 31a, an inner electromagnet power source 43a, an outer electromagnet power source 44a, an inner elevation drive member 45, and an outer elevation drive member 46.

The controller 50a may control the magnitude of the power that the antenna power source 31a applies to the antenna 30 by controlling the antenna power source 31a.

The controller 50a may control the magnitude of the power that the inner electromagnet power source 43a applies to the inner electromagnet 41a by controlling the inner electromagnet power source 43a.

The controller 50a may control the magnitude of the power that the outer electromagnet power source 44a applies to the outer electromagnet 42a by controlling the outer electromagnet power source 44a.

The inner electromagnet 41a and the outer electromagnet 42a may have the same or similar structure as the inner electromagnet 41 and the outer electromagnet 42 described above for FIG. 3.

The controller 50a may control a height (in the vertical direction) of the inner electromagnet 41a by controlling the inner elevation drive member 45. The inner elevation drive member 45 is connected to the inner electromagnet 41a, and may move (e.g., linearly translate) the inner electromagnet 41a in the vertical direction.

The controller 50a may control a height of the outer electromagnet 42a by controlling the outer elevation drive member 46. The outer elevation drive member 46 is connected to the outer electromagnet 42a, and may move the outer electromagnet 42a in the vertical direction.

Accordingly, the inner electromagnet 41a may be adjusted in position, such that the inner electromagnet 41a is disposed above the outer electromagnet 42a. In this case, the outer electromagnet 42a may be disposed at a height corresponding to the cover member 12, or may be disposed above the cover member 12.

In addition, the inner electromagnet 41a may be adjusted in position, such that the inner electromagnet 41a is disposed underneath the outer electromagnet 42a.

To this end, the controller 50a may move the inner electromagnet 41a up and down (vertically) by operating the inner elevation drive member 45. In addition, the controller 50a may move the outer electromagnet 42a up and down by operating the outer elevation drive member 46. In addition, the controller 50a may move the inner electromagnet 41a and the outer electromagnet 42a up and down by operating the inner elevation drive member 45 and the outer elevation drive member 46.

In a state positioned as described above, the controller 50a may control the inner electromagnet power source 43a and the outer electromagnet power source 44a in the same or similar manner as described above in connection with FIGS. 5 and 6. Accordingly, the direction of the magnetic line of force ML, the intensity of the magnetic line of force ML, the shape of the magnetic line of force ML, the points through which the magnetic line of force ML passes, the overall magnetic field distribution between the inner and outer electromagnets, and the like may be adjusted.

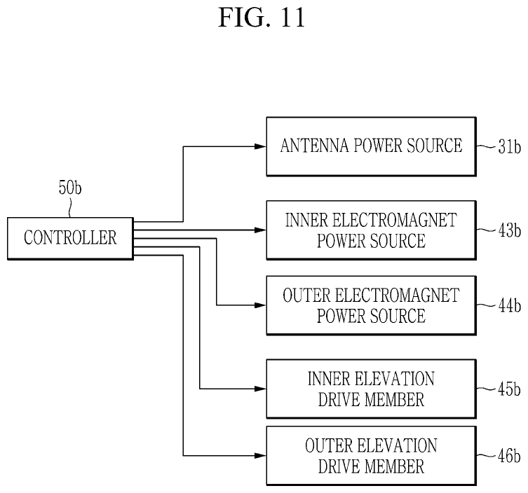

FIG. 10 is a cross-sectional view illustrating an inner electromagnet and an outer electromagnet, according to another embodiment, and FIG. 11 is a view illustrating control relationship of a substrate processing apparatus including the inner electromagnet and outer electromagnet of FIG. 10.

With reference to FIGS. 10 and 11, an inner electromagnet 41b may include a plurality of inner “sub-electromagnets” 411, 412 and 413 (each of which is an electromagnet that differs in size relative to the other sub-electromagnets). Each of the inner sub-electromagnets 411, 412, and 413 may be disposed on a circumference about a vertical axis that passes through the center area of the processing space 11. When viewed in a plan view from a distant point above or below the substrate processing apparatus 1, each of the inner sub-electromagnets 411, 412, and 413 may be concentric. In an example, each of the inner sub-electromagnets 411, 412, and 413 may be provided in a shape of a circular ring, an arc shape with one side cut from a circular ring, or the like. FIG. 10 illustrates a case where the inner electromagnet 41b includes three inner sub-electromagnets 411, 412 and 413. However, this is exemplary and the number of the inner sub-electromagnets 41b may differ in other embodiments.

An outer electromagnet 42b is disposed in an outer area of the inner electromagnet 41b. The outer electromagnet 42b may include a plurality of outer sub-electromagnets 421, 422, and 423, which may be disposed on a circumference about a vertical axis that passes through the center area of the processing space 11. When viewed from a distant point along the vertical axis, each of the outer sub-electromagnets 421, 422, and 423 may be concentric. The plurality of outer sub-electromagnets 421-423 and the plurality of inner electromagnets 411-413 may all be concentric. In an example, each of the outer sub-electromagnets 421, 422, and 423 may be provided in a shape of a circular ring, an arc shape with one side cut from a circular ring, or the like. FIG. 10 illustrates a case where the outer electromagnet 42b includes three outer sub-electromagnets 421-423. However, this is exemplary and the number of the outer electromagnets may differ in other embodiments. The number of the plurality of outer sub-electromagnets may be the same as or different from the number of the plurality of inner sub-electromagnets.

A controller 50b may control the magnitude of the power that an antenna power source 31b applies to the antenna 30 by controlling the antenna power source 31b.

The controller 50b may control the magnitude of the power that the inner electromagnet power source 43b applies to the inner electromagnet 41b by controlling the inner electromagnet power source 43b. The on-off and magnitude of the power applied to each of the plurality of inner electromagnets 411-413 may be controlled independently.

The controller 50b may control the magnitude of the power that the outer electromagnet power source 44b applies to the outer electromagnet 42b by controlling the outer electromagnet power source 44b. The on-off and magnitude of the power applied to each of the plurality of outer sub-electromagnets 421-423 may be controlled independently.

The controller 50b may control a vertical height of the inner electromagnet 41b by controlling an inner elevation drive member 45b. The inner elevation drive member 45b is connected to the inner electromagnet 41b, and may move the inner electromagnet 41b in the vertical direction. The inner elevation drive member 45b may independently move each of the plurality of inner sub-electromagnets 411-413 in the vertical direction.

The controller 50b may control a vertical height of the outer electromagnet 42b by controlling an outer elevation drive member 46b. The outer elevation drive member 46b is connected to the outer electromagnet 42b, and may move the outer electromagnet 42b in the vertical direction. The outer elevation drive member 46b may independently move each of the plurality of outer electromagnets 42b in the vertical direction.

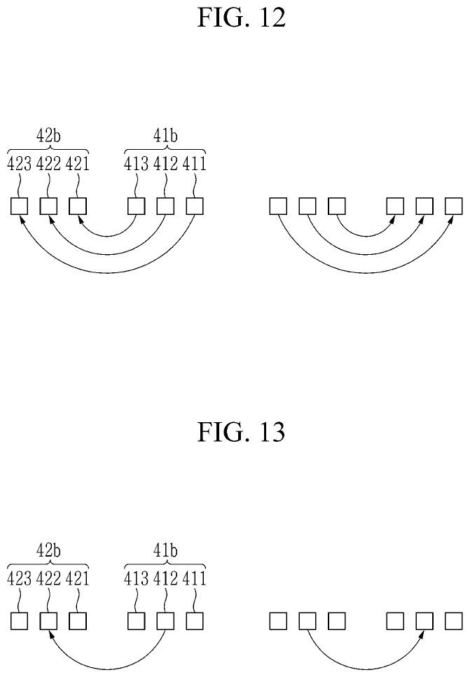

FIGS. 12 to 15 are views illustrating a case where a magnetic line of force ML is formed to be directed from a lower portion of the inner electromagnet to a lower portion of the outer electromagnet.

With reference to FIGS. 12 to 15, the controller 50b may control the inner electromagnet power source 43b and the outer electromagnet power source 44b such that the magnetic line of force ML is directed from a lower portion of at least one of the plurality of inner sub-electromagnets 411-413 to a lower portion of at least one of the plurality of outer sub-electromagnets 421-423.

As illustrated in FIG. 12, the controller 50b may control the inner electromagnet power source 43b and the outer electromagnet power source 44b such that the magnetic line of force ML is directed from a lower portion of all the plurality of inner sub-electromagnets 411-413 to a lower portion of all the plurality of outer sub-electromagnets 421-423.

In another example, as illustrated in FIG. 13, the controller 50b may control the inner electromagnet power source 43b and the outer electromagnet power source 44b such that the magnetic line of force ML is directed from a lower portion of one of the plurality of inner sub-electromagnets 411-413 to a lower portion of one of the plurality of outer sub-electromagnets 421-423.

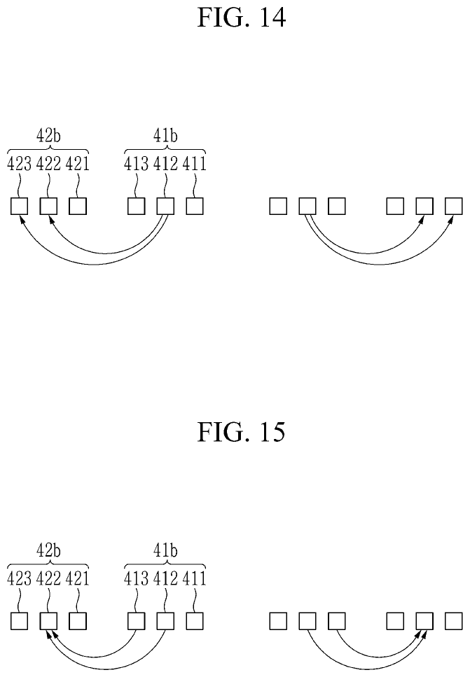

In another example, as illustrated in FIGS. 14 and 15, the controller 50b may control the inner electromagnet power source 43b and the outer electromagnet power source 44b such that at least one of the plurality of inner sub-electromagnets 411-413 and at least one of the plurality of outer electromagnets 421-423 is turned off. Accordingly, the magnetic line of force ML may be formed to be directed from a lower portion of the remaining inner electromagnet(s) 411-413 to which power is supplied to a lower portion of the remaining outer sub-electromagnet(s) 421-423 to which power is supplied. In this case, the number of the inner sub-electromagnets 411-423 of the plurality of inner sub-electromagnets 411-413 to which power is supplied and the number of the outer sub-electromagnets 421-423 of the plurality of outer electromagnets 421-423 to which power is supplied may be the same or different. In another example, the controller 50b may control the inner electromagnet power source 43b and the outer electromagnet power source 44b such that at least one of the plurality of inner sub-electromagnets 411-413 is turned off, such that the magnetic line of force ML is directed from the lower portion of the remaining inner electromagnet(s) 411-413 to which power is supplied to the lower portion of the plurality of outer electromagnets 421-423. In this case, when the inner sub-electromagnets 411-413 to which power is supplied are plural, the inner sub-electromagnets 411-413 to which power is supplied may be disposed adjacent to each other. In contrast, when the inner sub-electromagnets 411-413 to which power is supplied are plural, the turned-off inner sub-electromagnet(s) 411-423 may be disposed between the inner electromagnets 411-423 to which power is supplied.

In another example, the controller 50b may control the inner electromagnet power source 43b and the outer electromagnet power source 44b such that at least one of the plurality of outer sub-electromagnets 421-423 is turned off. Accordingly, the magnetic line of force ML may be formed to be directed from the lower portion of the plurality of inner sub-electromagnets 411-413 toward the lower portion of the remaining outer sub-electromagnet(s) 421-423 to which power is supplied. In this case, when the outer sub-electromagnets 421-423 to which power is supplied are plural, the outer sub-electromagnets 421-423 to which power is supplied may be disposed adjacent to each other. In contrast, when the outer sub-electromagnets 421-423 to which power is supplied are plural, the turned-off outer sub-electromagnet(s) 421-423 may be disposed between the outer sub-electromagnets 421-423 to which power is supplied.

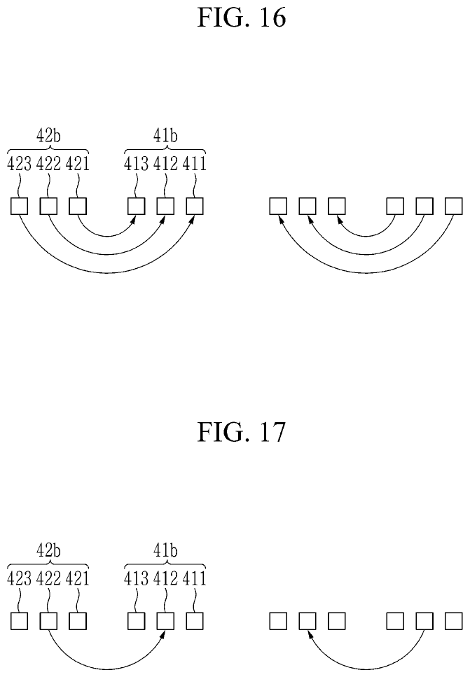

FIGS. 16 to 19 are views illustrating a case where a magnetic line of force is formed to be directed from the lower portion of the outer electromagnet to the lower portion of the inner electromagnet.

With reference to FIGS. 16 to 19, the controller 50b may control the outer electromagnet power source 43b and the outer electromagnet power source 44b such that the magnetic line of force ML is directed from a lower portion of at least one of the plurality of outer sub-electromagnets 421-423 to a lower portion of at least one of the plurality of inner sub-electromagnets 411-413.

As illustrated in FIG. 16, the controller 50b may control the inner electromagnet power source 43b and the outer electromagnet power source 44b such that the magnetic line of force ML is directed from the lower portion of all the plurality of outer sub-electromagnets 421-423 to the lower portion of all the plurality of inner electromagnets 411-413.

In addition, as illustrated in FIG. 17, the controller 50b may control the inner electromagnet power source 43b and the outer electromagnet power source 44b such that the magnetic line of force ML is directed from the lower portion of one of the plurality of outer sub-electromagnets 421-423 to the lower portion of one of the plurality of inner electromagnets 411-413.

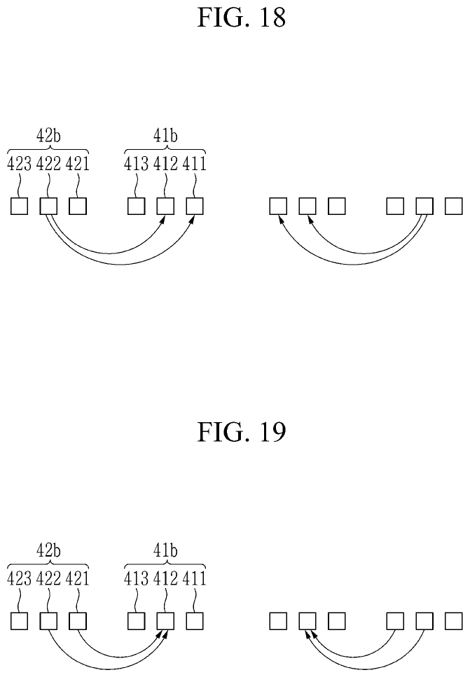

In another example, as illustrated in FIGS. 18 and 19, the controller 50b may control the inner electromagnet power source 43b and the outer electromagnet power source 44b such that at least one of the plurality of outer electromagnets 42b and at least one of the plurality of inner electromagnets 41b are turned off. Accordingly, the magnetic line of force ML may be formed to be directed from a lower portion of the remaining outer sub-electromagnet 421-423 to which power is supplied to a lower portion of the remaining inner sub-electromagnet 411-413 to which power is supplied. In this case, the number of the inner sub-electromagnets of the plurality of inner sub-electromagnets 411-413 to which power is supplied and the number of the outer sub-electromagnets of the plurality of outer sub-electromagnets 421-423 to which power is supplied may be the same or different. In another example, the controller 50b may control the inner electromagnet power source 43b and the outer electromagnet power source 44b such that at least one of the plurality of inner sub-electromagnets 411-413 is turned off, such that the magnetic line of force ML is directed from the lower portion of the plurality of outer sub-electromagnets 421-423 to the lower portion of the remaining inner electromagnets 411-413 to which power is supplied. In this case, when there are two or more inner sub-electromagnets 411-413 to which power is supplied, the inner electromagnets among 411-413 to which power is supplied may be disposed adjacent to each other. In contrast, when there are two or more inner sub-electromagnets 411-413 to which power is supplied, the turned-off inner sub-electromagnet among 411-413 may be disposed between the inner sub-electromagnets 411-413 to which power is supplied.

In addition, the controller 50b may control the inner electromagnet power source 43b and the outer electromagnet power source 44b such that at least one of the plurality of outer electromagnets 42b is turned off. Accordingly, the magnetic line of force ML may be formed to be directed from the lower portion of the remaining outer electromagnet 42b to which power is supplied to the lower portion of the plurality of inner electromagnets 41b. In this case, when the outer electromagnets 42b to which power is supplied are plural, the outer electromagnets 42b to which power is supplied may be disposed adjacent to each other. In contrast, when the outer electromagnets 42b to which power is supplied are plural, the turned-off outer electromagnet 42b may be disposed between the outer electromagnets 42b to which power is supplied.

In FIGS. 12 to 19 described above, the controller 50b may control the magnitude of the current applied to the plurality of inner sub-electromagnets 411-413 and the current applied to the plurality of outer sub-electromagnets 421-423, respectively. The controller 50b may control the magnitude of the sum of the current applied to the inner sub-electromagnet(s) among 411-413 to which power is supplied to be greater than the magnitude of the sum of the current applied to the outer sub-electromagnet(s) 421-423 to which power is supplied. In addition, the controller 50b may control the magnitude of the sum of the current applied to the inner electromagnet(s) among 411-413 to which power is supplied to be smaller than the magnitude of the sum of the current applied to the outer electromagnet 421-423 to which power is supplied. In another example, the controller 50b may control the magnitude of the sum of the current applied to the inner sub-electromagnet(s) 411-413 to which power is supplied to be the same as the magnitude of the sum of the current applied to the outer electromagnet(s) 421-423 to which power is supplied. In another example, the controller 50b may control the magnitude of the current applied to each of the inner sub-electromagnets 411-413 to be the same or different from each other. In another example, the controller 50b may control the magnitude of the current applied to each of the outer sub-electromagnets 421-423 to be the same or different from each other. Accordingly, the intensity of the magnetic line of force ML, the shape of the magnetic line of force ML, the overall magnetic field distribution, and the like may be adjusted.

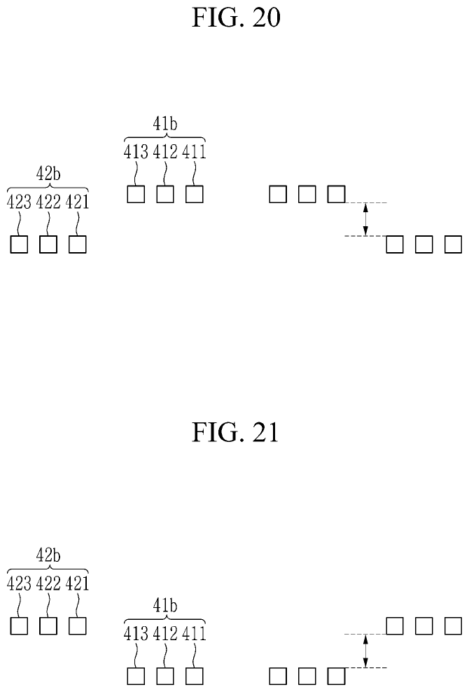

FIGS. 20 and 21 are views illustrating the vertical position relationship of a plurality of inner electromagnets and a plurality of outer electromagnets.

With reference to FIGS. 20 and 21, the plurality of inner electromagnets 41b may be adjusted in position, such that the plurality of inner electromagnets 41b are disposed above the plurality of outer electromagnets 42b.

In addition, the plurality of inner electromagnets 41b may be adjusted in position, such that the plurality of inner electromagnets 41b are disposed underneath and above the plurality of outer electromagnets 42b.

To this end, the controller 50b may move the plurality of inner electromagnets 41b up and down by operating the inner elevation drive member 45b. In addition, the controller 50b may move the plurality of outer electromagnets 42b up and down by operating the outer elevation drive member 46b. In addition, the controller 50b may move the plurality of inner electromagnets 41b and the plurality of outer electromagnets 42b up and down by operating the inner elevation drive member 45b and the outer elevation drive member 46b.

In a state positioned as described above, the controller 50b may control the inner electromagnet power source 43b and the outer electromagnet power source 44b in the same or similar manner as described above in FIGS. 12 to 19. Accordingly, the direction of the magnetic line of force ML, the intensity of the magnetic line of force ML, the disposition shape of the magnetic line of force ML according to the areas, the position through which the magnetic line of force ML passes, and the like may be adjusted.

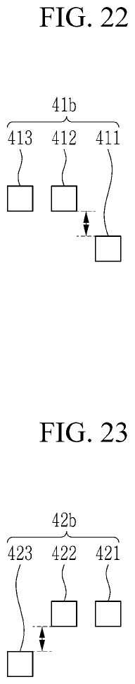

FIG. 22 is a view illustrating the vertical position relationship of a plurality of inner electromagnets, and FIG. 23 is a view illustrating the vertical position relationship of a plurality of outer electromagnets.

With reference to FIGS. 22 and 23, each of the plurality of inner sub-electromagnets 411-413 may be adjusted to have a different vertical height. To this end, the controller 50b may move at least one of the inner sub-electromagnets 411-413 relative to the remaining inner electromagnet(s) among 411-413 vertically by operating the inner elevation drive member 45b.

Each of the plurality of outer sub-electromagnets 421-423 may be adjusted to have a different height. To this end, the controller 50b may move at least one of the outer electromagnets 421-423 relative to the remaining outer electromagnet(s) 421-423 up and down by operating the outer elevation drive member 46b.

Adjusting the height of each of the plurality of inner sub-electromagnets 411-413 and adjusting the height of each of the plurality of outer sub-electromagnets 421-423 may be performed together. Accordingly, at least one of the plurality of inner sub-electromagnets 411-413 may be positioned between the highest positioned outer sub-electromagnet and the lowest positioned outer sub-electromagnet among the plurality of outer sub-electromagnets 421-423. In addition, at least one of the plurality of outer sub-electromagnets 421-423 may be positioned between the highest positioned inner sub-electromagnet and the lowest positioned inner sub-electromagnet among the plurality of inner electromagnets 411-413.

Although embodiments of the present disclosure have been described in detail hereinabove, the scope of the present disclosure is not limited thereto, and it should be clearly understood that many variations and modifications made by those skilled in the art using the basic concepts of the present disclosure fall within the scope of the present disclosure as defined by the appended claims and their equivalents.

What is claimed is:

1. A substrate processing apparatus comprising:
a chamber providing a processing space;
a support member disposed in the processing space and configured to support a substrate during a process treatment of the substrate;
an antenna providing energy for plasma excitation into the processing space; and
an inner electromagnet disposed outside the processing space.

2. The substrate processing apparatus of claim 1, wherein the inner electromagnet has a surface facing the processing space.

3. The substrate processing apparatus of claim 1, wherein the inner electromagnet is disposed on a circumference about a vertical axis that passes through a center area of the processing space.

4. The substrate processing apparatus of claim 3, wherein the inner electromagnet has a shape of a circular ring.

5. The substrate processing apparatus of claim 1, wherein the inner electromagnet comprises a plurality of inner sub-electromagnets.

6. The substrate processing apparatus of claim 5, wherein the plurality of inner sub-electromagnets are concentric about a vertical axis that passes through a center area of the processing space.

7. The substrate processing apparatus of claim 1, further comprising:
an inner elevation drive member configured to move the inner electromagnet vertically.

8. The substrate processing apparatus of claim 1, further comprising:
an outer electromagnet disposed outside the processing space.

9. The substrate processing apparatus of claim 8, wherein the outer electromagnet is disposed outside a perimeter of the inner electromagnet.

10. The substrate processing apparatus of claim 8, wherein the outer electromagnet is disposed on a circumference about a vertical axis that passes through a center area of the processing space.

11. The substrate processing apparatus of claim 10, wherein the outer electromagnet has a shape of a circular ring.

12. The substrate processing apparatus of claim 10, wherein
the inner electromagnet and the outer electromagnet are concentric.

13. The substrate processing apparatus of claim 8, wherein the outer electromagnet comprises a plurality of outer sub-electromagnets.

14. The substrate processing apparatus of claim 13, wherein:
the plurality of outer electromagnets are concentric about a vertical axis that passes through a center area of the processing space.

15. The substrate processing apparatus of claim 8, further comprising:
an outer elevation drive member configured to move the outer electromagnet vertically.

16. A substrate processing apparatus comprising:
a chamber providing a processing space;
a cover member disposed on an upper portion of the chamber and configured to shield the processing space;
a support member disposed in the processing space and configured to support a substrate during a process treatment of the substrate;
an antenna providing energy for plasma excitation into the processing space;
an inner electromagnet disposed outside the processing space and having an annular surface facing the processing space with the cover member therebetween; and
an outer electromagnet disposed outside the processing space and disposed outside a perimeter of the inner electromagnet.

17. The substrate processing apparatus of claim 16, comprising:
an inner electromagnet power source electrically connected to the inner electromagnet;
an outer electromagnet power source electrically connected to the outer electromagnet; and
a controller configured to control the inner electromagnet power source and the outer electromagnet power source such that a magnetic line of force is formed in a direction from one of a lower portion of the inner electromagnet and a lower portion of the outer electromagnet to the other thereof.

18. The substrate processing apparatus of claim 16, further comprising:
an inner elevation drive member configured to move the inner electromagnet vertically.

19. The substrate processing apparatus of claim 16, further comprising:
an outer elevation drive member configured to move the outer electromagnet vertically.

20. A substrate processing apparatus comprising:
a chamber providing a processing space;
a cover member disposed on an upper portion of the chamber and configured to shield the processing space;
a support member disposed in the processing space and configured to support a substrate during a process treatment of the substrate;
an antenna providing energy for plasma excitation into the processing space;
an inner electromagnet disposed outside the processing space and having an annular surface facing the processing space with the cover member therebetween; and
an outer electromagnet disposed outside the processing space and outside a perimeter of of the inner electromagnet, wherein:
the cover member comprises:
a cover frame having a plate structure and coupling slots between portions of the plate structure, each of the coupling slots including a dielectric window.
